(19) United States
(12) Patent Application Publication
(10) Pub. No.: US 2006/0043562 A1
(43) Pub. Date: Mar. 2, 2006

(54) Circuit device and manufacture method for circuit device

(76) Inventor: Yoshio Watanabe, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/212,655

(22) Filed: Aug. 29, 2005

(30) Foreign Application Priority Data
Aug. 31, 2004 (JP) P2004-253592

(51) Int. Cl. H01L 23/02; H01L 23/52; H01L 21/50; H01L 21/48; H01L 21/44

(52) U.S. Cl. 257/686; 257/758; 438/106; 438/455; 438/107

(57) ABSTRACT

There is provided a circuit device including a plurality of circuit blocks, wherein: on one surface of an insulating sheet having flexibility, a first and a second wiring patterns are formed, the second wiring pattern including a plurality of divisionally disposed patterns and electrically connected to the first wiring pattern; in an area corresponding to the second wiring pattern on another surface of the insulating sheet, a third wiring pattern including a plurality of patterns is formed and electrically connected to the second wiring pattern via a conductive hole; electronic components are mounted on the third wiring pattern so as to form the divisionally disposed circuit blocks; the plurality of circuit blocks are folded by directing the electronic component mounting surface of the insulating sheet inward and the second wiring pattern outward; and insulating resin having electromagnetic shielding effect is filled in gaps between the plurality of folded circuit blocks.

### BACKGROUND OF THE INVENTION

1. Field of the Invention

The present invention relates to a circuit device using a plurality of circuit blocks connected together without connectors and being particularly suitable for high frequency use and to a manufacture method for the circuit device of this type.

2. Description of Related Art

As a conventional method of connecting, e.g., two circuit blocks, there are a method of connecting a flexible cable board between two connectors of two wiring boards mounting each circuit block, a method of mounting two circuit blocks on a wiring board having not a connector but a flexible part and mounting the wiring board in a narrow space of a product by utilizing flexibility of the flexible part, and other methods. These methods are generally adopted in assembling electric products. A method is disclosed as an example of the latter in Japanese Patent Unexamined Publication No. 2001-358422 (FIG. 5).

Furthermore, for example, a plurality of circuit devices or the like, which are formed by mounting IC chips etc on wiring boards of ceramic packages etc so as to perform predetermined functions, are connected by placing one circuit device on the top of another circuit device and connecting upperside terminals of one circuit device to lowerside ones of another circuit device with soldering etc, thereby enabling mass production of such circuit devices.

Connectors are unsatisfactory in that they raise cost, and since mount spaces are required for wiring boards, products have a disadvantage in compactness and is weak against vibrations and the like. Although there is a thin connector using a flexible cable, this is not satisfactory in cost, space and connection reliability.

The structure that a flexible part is integrally connected to two circuit blocks has no problem of connection reliability between the circuit blocks. However, if a circuit sensitive to electromagnetic interferences or the like is mounted, electromagnetic interferences between circuit blocks pose a problem and two circuit blocks may not be used by folding them, resulting in the necessity of a shield case or the like. Since the shield case requires some area and thickness, it obstructs compactness. In addition, a shield case made of a metal plate generally adopted has good thermal absorption so that there is a fear of soldering defects because a soldering temperature may not be raised sufficiently.

### SUMMARY OF THE INVENTION

By considering these problems, it is desirable to provide a circuit device having a narrow mount area and using two or more circuit blocks connected without using connectors, and a manufacture method for the circuit device of this type.

According to one embodiment of the present invention, there is provided a circuit device having a plurality of circuit blocks, wherein: on one surface of a bendable insulating sheet made of, for example, polyimide resin, a first wiring pattern and a second wiring pattern are formed, the second wiring pattern including patterns divisionally disposed in respective circuit blocks and electrically connected to the first wiring pattern; in an area corresponding to the second wiring pattern on another surface of the insulating sheet, a third wiring pattern including patterns divisionally disposed in respective circuit blocks is formed and connected to the second wiring pattern; electronic components are mounted on the third wiring pattern to form a plurality of divisionally disposed circuit blocks; the plurality of circuit blocks are folded by directing an electronic component mounting surface inward; and insulating resin having electromagnetic shielding effects, for example epoxy-based resin dispersed with ferrite powders and ceramic powders, is filled in gaps between the plurality of folded circuit blocks.

According to the circuit device of the embodiment of the present invention configured in this manner, the plurality of circuit blocks are electrically connected by the plurality of first wiring patterns disposed between the plurality of circuit blocks, electronic components mounted in the third wiring pattern are disposed inside, the plurality of circuit blocks are folded in a rolling manner, and the insulating resin having the electromagnetic shielding effects is filled in the gaps between the plurality of folded circuit blocks. Accordingly, mutual interferences between the mounted electronic components may be prevented.

A performance test, for example, an operation test or the like, may be conducted after the electronic components are mounted on the circuit blocks. Accordingly, defects may be removed before the circuit blocks are folded to form circuit devices. Therefore, the circuit device having built-in electronic components may be produced at a good yield and with a low cost.

Since the insulating resin made of mainly epoxy resin is filled between the electronic components, electric insulation may be improved and the reliability of the circuit device may be improved.

Further, by using the insulating resin containing aluminum nitride, boron nitride and the like, heat from the electronic components may be diffused to the whole circuit device so that the heat radiation characteristics may be improved considerably.

In the circuit device of another embodiment of the present invention described above, the circuit device may have two circuit blocks, the first wiring pattern is used as a first flexible wiring part, the second wiring patterns are external layer wiring patterns, third wiring patterns are internal layer wiring patterns, the two circuit blocks are folded in a U-character shape by directing the electronic component mounting surface of the two circuit blocks inward and the first flexible wiring part outward.

According to the circuit device of the embodiment of the present invention configured in this manner, the electronic component mounting surfaces of the two circuit blocks on the side of the inner layer wiring pattern side face one another, and the two circuit blocks are electrically connected by the first wiring pattern constituting the first flexible wiring part bent in the U-character shape, so that the circuit blocks may be covered with the outer layer wiring pattern. Further, since the insulating resin having the electromagnetic shielding effects is filled in a gap between the two circuit blocks, mutual interferences between the mounted electronic devices may be prevented effectively.

In the circuit device of another embodiment of the present invention, conductive spacers may be provided for connecting the inner layer wiring patterns of the facing circuit blocks and setting a predetermined gap when the circuit blocks are folded.

According to the circuit device of the embodiment of the present invention configured in this manner, not only an excessive stress may be prevented from being concentrated upon the mounted electronic components and connection regions between the mounted electronic components and corresponding wiring patterns, while both the blocks are folded, but also electric connection between the two circuit blocks may be performed independently from that of the first wiring pattern (first flexible wiring part) so that designs of the circuit blocks and mount designs of the electronic components become easy.

In the circuit device of another embodiment of the present invention described above, the outer layer wiring patterns of the two circuit blocks and the first flexible wiring part may constitute an electromagnetic shield layer.

According to the circuit device of the embodiment of the present invention configured in this manner, the insulating resin having the electromagnetic shielding effects and filled in the gap between the two circuit blocks may effectively prevent mutual interferences between the mounted electronic components and suppress electromagnetic interferences of the circuit blocks to an external. It is therefore possible to provide a circuit block with less erroneous operations even at a high frequency.

In the circuit device of another embodiment of the present invention described above, in the state that the two circuit blocks may be folded, the ends of the two circuit blocks on the side opposite to the first flexible wiring part are bonded together by low melting point metal or conductive adhesive.

According to the circuit device of the embodiment of the present invention configured as above, the outer size stability of the circuit device may be retained even at a peripheral temperature more than only the resin is filled in the gap between the two folded circuit blocks.

In the circuit device of another embodiment of the present invention described above, a second flexible wiring part may be extended from an end of the circuit block. Contact terminals to another circuit are formed on the wiring pattern of the second flexible wiring part.

According to the circuit device of the embodiment of the present invention configured as above, another circuit may be electrically connected to the tip or intermediate wiring pattern of the second flexible wiring part extended from the end of the circuit block and formed at the same time when the two circuit blocks and first flexible wiring part are manufactured.

In the circuit device of another embodiment of the present invention described above, a third flexible wiring part extending from a ground layer at the end of the circuit block may be formed. The third flexible wiring part is folded on the electronic component mounting surface side and an electromagnetic shield layer is constituted of the outer layer wiring patterns and first flexible wiring part.

According to the circuit device of the embodiment of the present invention configured as above, an electromagnetic shield layer is formed on the third flexible wiring part extended from the end of the circuit block and formed at the same time when the two circuit blocks and first flexible wiring part are manufactured. The third flexible wiring part is disposed covering one circuit block and then the other circuit block is folded. Accordingly, electromagnetic interferences may be further suppressed between mounted electronic components of the two circuit blocks. Moreover, the areas of the power source and ground may be broadened so that stable operations are possible.

According to another embodiment of the present invention, there is provided a manufacture method for a circuit device having a plurality of circuit blocks which includes a step of forming first wiring patterns on an insulating sheet made of, for example, polyimide resin, a step of laminating an insulating layer and copper foil for forming second and third wiring patterns for each divisionally disposed circuit block, a step of forming conductive holes for connection of necessary regions of the first, second and third wiring patterns, a step of forming the second and third wiring patterns, a step of forming solder resist on the third wiring patterns, a step of mounting electronic components on the third wiring patterns to thereby form a plurality of circuit blocks relative to the divisionally disposed second and third wiring patterns, a process of folding the circuit patterns by directing an electronic component mounting surface side of the insulating sheet inward and the first wiring patterns outward, a process of filling insulating resin having electromagnetic shielding effects, such as epoxy resin dispersed, for example, with ferrite powders and ceramic powders, between the electronic component mounting surfaces of the plurality of folded circuit blocks, and a process of heating and curing the insulating resin.

According to the manufacture method for a circuit device of the embodiment of the present invention configured as above, on both sides of the insulating sheet, the conductive wiring patterns such as plated copper and conductive paste are formed by a photolithography method or a printing method, and after the wiring patterns on both sides are electrically connected, the electronic components are mounted to thereby form the plurality of circuit blocks. In this case, the circuit blocks are electrically connected by the first wiring patterns disposed on one side of the insulating sheet. Accordingly, by folding the plurality of circuit blocks at the first wiring patterns and filling the insulating resin having the electromagnetic shielding effects between the plurality of circuit blocks and curing the insulating resin, it becomes possible to manufacture a circuit device with less mutual interferences between mounted electronic components.

According to the circuit device and the manufacture method for a circuit device of embodiments of the present invention, it is possible to conduct a performance test, for example, an operation test or the like when electronic components are mounted in the circuit blocks and remove defects before the circuit blocks are folded to form the circuit devices. Accordingly, a circuit device having built-in electronic components may be produced at a good yield and with a low cost. Since the insulating resin made of mainly epoxy resin is filled between the electronic components, electric insulation may be improved and the reliability of the circuit device may be improved. Further, heat generated in the electronic components may be diffused to the whole circuit device via the filled resin and the wiring patterns of the circuit blocks, so that the heat radiation characteristics may be improved considerably.

Since the structure that the circuit device is covered with electromagnetic shielding may be adopted easily, the electromagnetic shielding between the circuit blocks and to an external is possible. Therefore, not only a excessive shield case and the like are not necessary but also interferences to an external may be avoided, facilitating an electromagnetic shielding countermeasure.

Since the folded and stacked structure is used, a circuit device provides three-dimensional space savings.

### BRIEF DESCRIPTION OF THE DRAWINGS

FIGS. 1A to 1E are manufacture process flow diagrams illustrating a manufacture method for a circuit device according to an embodiment of the present invention. FIG. 1A is a cross sectional view of a four-layer flex-rigid board, FIG. 1B is a cross sectional view of the board after conductive paste is coated, FIG. 1C is a cross sectional view of the board after electronic components are mounted, FIG. 1D is a cross sectional view of the board after insulating resin is coated, and FIG. 1E is a cross sectional view of the circuit device formed through folding and curing.

FIGS. 2A to 2E are manufacture process flow diagrams illustrating a manufacture method for a circuit device according to another embodiment of the present invention. FIG. 2A is a cross sectional view of a four-layer flex-rigid board, FIG. 2B is a cross sectional view of the board after conductive paste is coated, FIG. 2C is a cross sectional view of the board after spacer pins are mounted upright, FIG. 2D is a cross sectional view of the board after it is folded, and FIG. 2E is a cross sectional view of the circuit device formed by filling and curing insulating resin.

FIGS. 3A to 3D are manufacture process flow diagrams illustrating a manufacture method for a circuit device according to another embodiment of the present invention. FIG. 3A is a cross sectional view of circuit blocks having a flexible connector, FIG. 3B is a cross sectional view of the circuit blocks after they are folded, FIG. 3C is a cross sectional view of the circuit device formed by filling and curing insulating resin, and FIG. 3D is an enlarged perspective view of a flexible connector tip.

FIGS. 4A and 4B are manufacture process flow diagrams illustrating a manufacture method for a circuit device according to another embodiment of the present invention. FIG. 4A is a cross sectional view of circuit blocks after a flexible wiring part is disposed between the circuit blocks, and FIG. 4B is a cross sectional view of the circuit device formed by filling and curing insulating resin.

FIGS. 5A to 5C are diagrams illustrating another manufacture method for the circuit device shown in FIG. 1E. FIG. 5A is a plan view showing a multi-device board mounted on a heating jig, FIG. 5B is an enlarged cross sectional view taken along line S-S of the circuit device folded in the jig, and FIG. 5C is a perspective view of a discrete circuit device.

### DESCRIPTION OF THE PREFERRED EMBODIMENT

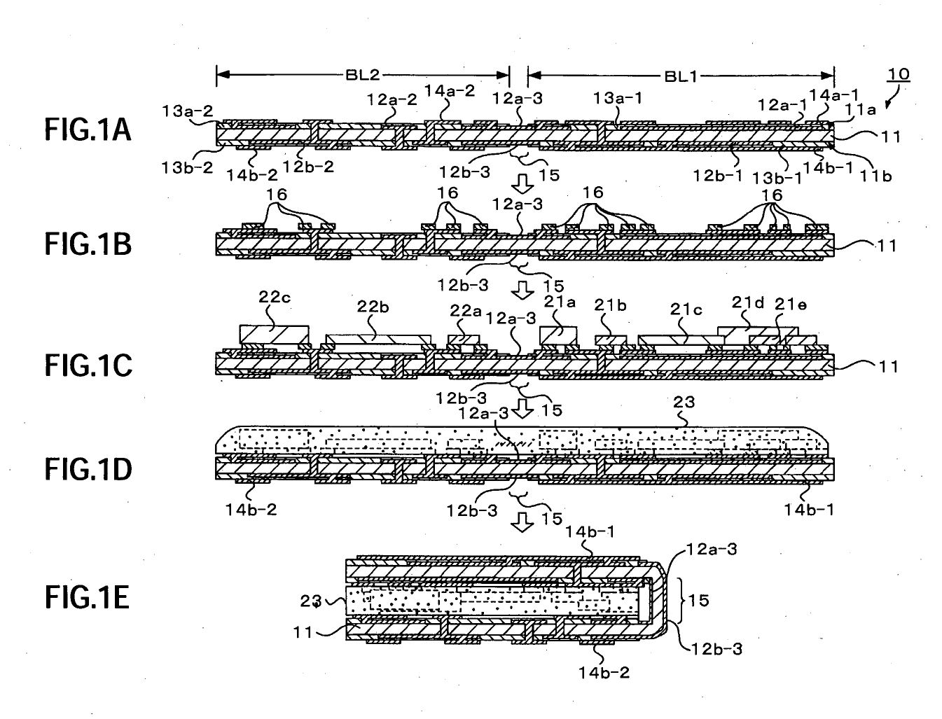

With reference to FIGS. 1A to 1E, description will be made on a preferred embodiment of a circuit device and a manufacture method for a circuit device of the present invention.

FIGS. 1A to 1E are manufacture process flow diagrams illustrating a manufacture method for a circuit device according to the embodiment. The circuit device is manufactured by using a four-layer flex-rigid board as a base member.

FIG. 1A is a cross sectional view of a four-layer flex-rigid board, FIG. 1B is a cross sectional view of the board after conductive paste is coated, FIG. 1C is a cross sectional view of the board after electronic components are mounted, FIG. 1D is a cross sectional view of the board after insulating resin is coated, and FIG. 1E is a cross sectional view of the circuit device formed through folding and curing.

In FIGS. 1A to 1E, reference numeral 10 represents the four-layer flex-rigid board, reference numeral 11 represents a polyimide sheet made of polyimide resin used as an insulating base member, reference numeral 12 represents wiring patterns formed on both surfaces of the polyimide sheet 11, reference numeral 13 represents insulating layers made of epoxy resin and covering regions BL1 and BL2 of the wiring patterns 12, and reference numeral 14 represents wiring patterns formed on the insulating layers 13.

Reference numeral 15 represents a flexible wiring part having flexibility and forming a wiring pattern 12b-3 on the polyimide sheet 11 in a border area between the regions BL1 and BL2, with the epoxy resin insulating layer being removed. Reference numeral 21 represents electronic components mounted in the region BL1 and constituting, e.g., a high frequency signal processing circuit, and reference numeral 22 represents electronic components mounted in the region BL2 and constituting, e.g., an intermediate frequency signal processing circuit. Reference numeral 23 represents sealing resin as a cover coat of the whole electronic component mounting surface.

The region BL1 corresponds to a portion of the wiring board where a high frequency signal processing circuit block mounted with electronic components is formed, whereas the region BL2 corresponds to a portion of the wiring board where an intermediate frequency signal processing circuit block mounted with electronic components is formed. Both the circuit blocks are electrically connected by the flexible wiring part 15.

FIG. 1E is a cross sectional view of the circuit device of the embodiment after a final process. The manufacture method for the circuit device will be sequentially described.

In the following, the four-layer flex-rigid board 10 shown in FIG. 1A as the base member will be described by dividing the method into first to ninth stages.

The flex-rigid board 10 is constituted of the flexible wiring part 15 (wiring pattern 12b-3) made of the polyimide sheet 11 as the base and the regions BL1 and BL2 made of rigid boards having the interlayer insulating layers (13a-1, 13a-2, 13b-1, 13b-2) made of cured glass epoxy resin. Namely, the wiring board is made of a mixture of the foldable flexible part (wiring pattern 12b-3) 15 and a rigid part (regions BL1 and BL2) mounted with electronic components.

Namely, for example, at the first stage, through holes are formed through the thin polyimide sheet 11 shown in FIG. 1A at predetermined positions by punching using laser or press work, and plating is performed on the whole board surface.

At the second stage, wiring patterns 12a-1 and 12b-1 are formed in the region BL1 of the polyimide sheet 11 shown in FIG. 1A and wiring patterns 12a-2 and 12b-2 are formed in the region BL2. In the border area between the regions BL1 and BL2, wiring patterns 12a-3 and 12b-3 are formed, the former electrically connecting the wiring patterns 12a-1 and 12a-2 and the latter electrically connecting the wiring patterns 12b-1 and 12b-2. A cover coat is formed over the whole surface.

At the third stage, glass epoxy resin and copper foil are laminated covering the upper and lower surfaces of the regions BL1 and BL2, and heated to form the insulating layers 13a-1, 13a-2, 13b-1 and 13b-2. Conductive holes for connection with the wiring patterns 12a-1, 12a-2, 12b-1 and 12b-2 are formed by laser work and plating.

At the fourth stage, as the uppermost layer, wiring patterns 14a-1 and 14b-1 are formed in the region BL1, and wiring patterns 14a-2 and 14b-2 are formed in the region BL2. The wiring pattern 14b-1 is formed covering almost the whole surface of the region BL1 to function as an electromagnetic shield layer. The wiring pattern 14b-2 is formed to have grid lands of generally a lattice shape in order to electrically connect the circuit device (FIG. 1E) to another wiring board or the like.

Next, as shown in FIG. 1B, conductive pastes 16 are formed on the upper surface of the four-layer flex-rigid board 10 as viewed in FIG. 1B at positions where electronic components are mounted, by a printing or dispensing method.

Next, as shown in FIG. 1C, electronic components are mounted on the four-layer flex-rigid board 10. In the region BL1, electronic components 21a, 21b, 21c, 21d and 21e constituting the high frequency signal processing circuit are mounted to form a first circuit block. In the region BL2, electronic components 22a, 22b and 22c constituting the intermediate frequency signal processing circuit are mounted to form a second circuit block. Thereafter, in the state that the electronic components are mounted on the four-layer flex-rigid board 10, a performance test, for example, an operation test or the like, is conducted in the unit of a circuit block.

Next, as shown in FIG. 1D, the sealing resin 23 is coated on the whole electronic components 21a to 21e and 22a to 22c mounting surfaces of the four-layer flexible-rigid board 10 and preliminarily dried to impart electromagnetic shielding effects. The sealing resin is made of epoxy resin excellent in electric insulation dispersed with ferrite powders and ceramic powders.

Next, as shown in FIG. 1E, the flexible wiring part 15 having the wiring patterns 12a-3 and 12b-3 formed in the border area between the first circuit block (region BL1) and second circuit block (region BL2) is bent in a U-character shape by directing the coating surface of the sealing resin 23 inward and the conductor of the wiring pattern 12b-3 outward, to thereby stack the first circuit block upon the second circuit block. In this manner, the electromagnetic shield layer of the wiring pattern 14b-1 is disposed on the upper surface and the grid lands by the wiring pattern 14b-2 are disposed on the lower surface.

Lastly, as shown in FIG. 1E, this structure is accommodated in an unrepresented jig at a predetermined thickness, heated and cured to form the electronic device of the embodiment.

According to the circuit device and the manufacture method for a circuit device of the embodiment shown in FIGS. 1A to 1E, a performance test, for example, an operation test or the like, is conducted after the electronic components 21a to 21e and 22a to 22c of the first and second circuit blocks are mounted and defects are removed before the structure is folded to form a final circuit device. Therefore, the circuit device having the built-in electronic components 21a to 21e and 22a to 22c may be produced at a good yield and with a low cost.

The insulating resin having the electromagnetic shield effects made of mainly epoxy resin is filled between the electronic components 21a to 21e of the high frequency signal processing circuit and the electronic components 22a to 22c of the intermediate frequency processing circuit. It is therefore possible to improve insulation, to considerably suppress mutual interference among electronic components and to improve reliability of the electronic device.

The structure that the circuit device is covered with an electromagnetic shield may be adopted easily. Therefore, the electromagnetic shield between the circuit blocks and to an external becomes perfect. Not only a shield case or the like is unnecessary, but also adverse effects to the external may be avoided so that the electromagnetic shield countermeasure may be performed easily.

Further, since heat from the electronic components may be diffused to the whole circuit device, the heat radiation characteristics may be improved considerably.

Furthermore, since a folded structure is realized, the circuit device provides three-dimensional space savings.

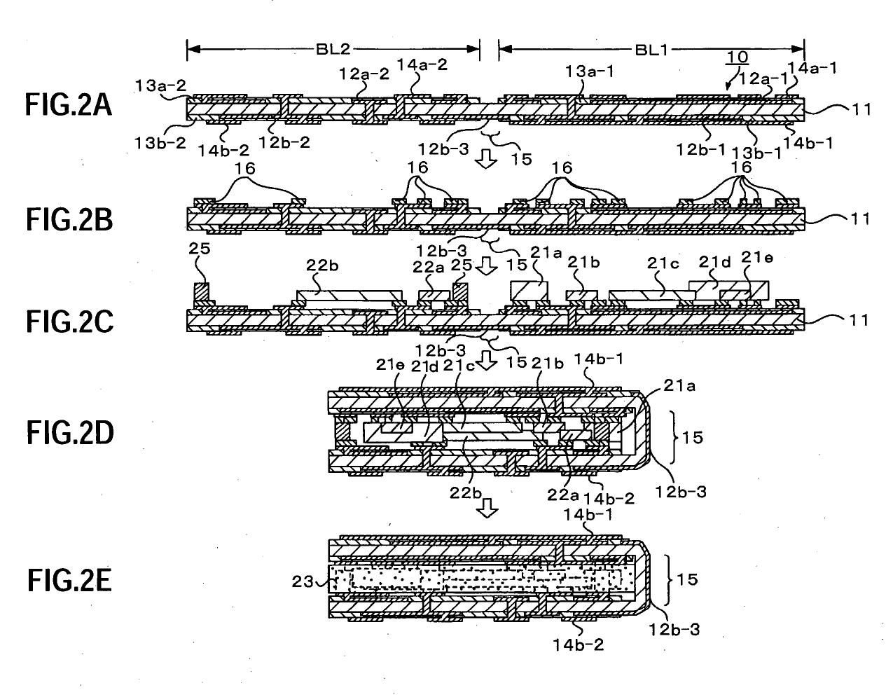

With reference to FIGS. 2A to 2E, description will be made on another preferred embodiment of a circuit device and a manufacture method for a circuit device of the present invention.

As compared to the circuit device of the embodiment shown in FIGS. 1A to 1E, the circuit device of the embodiment shown in FIGS. 2A to 2E is different in that height adjusting pins are mounted at the same time when electronic components are mounted and that the sealing resin 23 is filled after folding. In the following description of the embodiment shown in FIGS. 2A to 2E, similar elements to those of FIGS. 1A to 1E are represented by using identical reference symbols.

Similar to the circuit device shown in FIGS. 1A to 1E, the circuit device of the embodiment is manufactured by using a four-layer flex-rigid board as a base member. FIGS. 2A to 2E are manufacture process flow diagrams illustrating a manufacture method for the circuit device.

FIG. 2A is a cross sectional view of a four-layer flex-rigid wiring board, FIG. 2B is a cross sectional view of the board after conductive paste is coated, FIG. 2C is a cross sectional view of the board after electronic components and space retaining pins are mounted, FIG. 2D is a cross sectional view of the board after it is folded, and FIG. 2E is a cross sectional view of the circuit device formed by filling, heating and curing insulating resin.

First, as shown in FIG. 2A, a four-layer flex-rigid board 10 is prepared having the same structure as that shown in FIG. 1A.

Next, as shown in FIG. 2B, similar to the description made with reference to FIG. 1B, conductive pastes 16 are formed on the upper surface of the four-layer flex-rigid board 10 as viewed in FIG. 2B at positions where electronic components are mounted, by a printing or dispensing method.

Next, as shown in FIG. 2C, similar to the description made with reference to FIG. 1C, electronic components are mounted on the four-layer flex-rigid substrate 10. In the region BL1, electronic components 21a, 21b, 21c, 21d and 21e constituting an analog signal processing circuit are mounted to form a first circuit block. In the region BL2, electronic components 22a, and 22b constituting a digital signal processing circuit are mounted to form a second circuit block. A pin 25 made of good conductor such as copper is mounted upright by using conductive paste or the like, for example, at four corners of the second circuit block.

These pins 25 maintain a predetermined gap between the first circuit block (region BL1) and second circuit block (region BL2) when both are folded, and contribute to shape stability by adhering and fixing both the blocks. Further, if necessary, the pins electrically connect wiring patterns 12a-1 and 14a-1 on the electronic component 21a to 21e mounting surface side in the region BL1 and, wiring patterns 12a-2 and 14a-2 on the electronic components 22a and 22b mounting surface side in the region BL2.

Next, as shown in FIG. 2D, a flexible wiring part 15 having wiring patterns 12a-3 and 12b-3 formed in the border area between the first circuit block (region BL1) and second circuit block (region BL2) is bent in a U-character shape by directing the side mounting the electronic components 21a to 21e and 22a and 22b inward and the conductor of the wiring pattern 12b-3 outward, to thereby stack the first circuit block upon the second circuit block. In this manner, the electromagnetic shield layer of the wiring pattern 14b-1 is disposed on the upper surface, and grid lands by a wiring pattern 14b-2 are disposed on the lower surface. A predetermined gap between both the blocks is maintained by the pins 25.

Next, as shown in FIG. 2E, a sealing resin 23 is filled in the gap between the first and second circuit blocks folded in the U-character shape to impart electromagnetic shielding effects. The sealing resin 23 is made of epoxy resin excellent in electric insulation dispersed with ferrite powders and ceramic powders. This structure is accommodated so as to keep the shape shown in the figure, for example, in a jig at a predetermined thickness, heated and cured to form the electronic device of the embodiment.

It may be understood easily that the circuit device and the manufacture method for a circuit device of the embodiment shown in FIGS. 2A to 2E may obtain similar operations and effects to those of the embodiment shown in FIGS. 1A to 1E.

Furthermore, in the embodiment shown in FIGS. 2A to 2E, the pins 25 are mounted upright and the first circuit block (region BL1) and second circuit block (region BL2) are adhered and fixed by using conductive paste. Therefore, both the blocks are maintained at a predetermined distance, and not only an excessive stress may be prevented from being concentrated upon connection regions between the mounted electronic components and corresponding wiring patterns, while both the blocks are folded, but also the pins contribute to shape stability by adhering and fixing both the blocks. Further, if necessary, the pins electrically connect the wiring patterns 12a-1 and 14a-1 and the wiring patterns 12a-2 and 14a-2 folded and facing one another, so that designs of the circuit blocks and mount designs of the electronic components become easy.

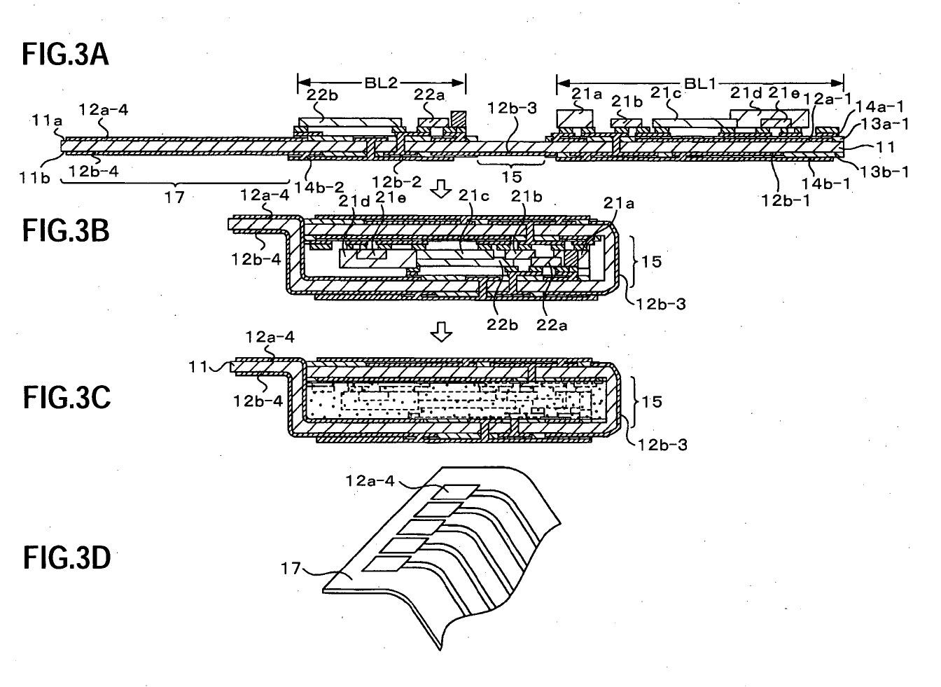

With reference to FIGS. 3A to 3D, description will be made on another preferred embodiment of a circuit device and a manufacture method for a circuit device of the present invention.

As compared to the circuit device of the embodiment shown in FIGS. 1A to 1E, the circuit device of the embodiment shown in FIGS. 3A to 3D is different in that a polyimide sheet 11 is extended from the end of the second circuit block, a connector formed by a conductive wiring pattern is provided on a top end portion, and a sealing resin 23 is filled after the board is folded similar to the embodiment shown in FIGS. 2A to 2E. In the following description of the embodiment shown in FIGS. 3A to 3D, similar elements to those of FIGS. 1A to 1E are represented by using identical reference symbols.

The circuit device of the embodiment is also manufactured by using a four-layer flex-rigid board as a base member. FIGS. 3A to 3D are manufacture process flow diagrams illustrating a manufacture method for the circuit device.

FIG. 3A is a cross sectional view of circuit blocks having a flexible connector, FIG. 3B is a cross sectional view of the circuit blocks after they are folded, FIG. 3C is a cross sectional view of the circuit device formed by filling and curing insulating resin, and FIG. 3D is an enlarged perspective view of a flexible connector tip.

First, a four-layer flex-rigid board 10 mounted with electronic components is formed as shown in FIG. 3A.

The four-layer flex-rigid board 10 has a polyimide sheet 11 extended further to the left in FIG. 3A as different from the polyimide sheet 11 in the region BL2 shown in FIG. 1A. On an upper surface 11a of the extended polyimide sheet 11, a wiring pattern 12a-4 is formed and on a lower surface 11b, a wiring pattern 12b-4 is formed to thereby form a flexible connector part 17. Similar to the embodiment shown in FIGS. 1A to 1E, as shown in FIG. 3A, conductive pastes are formed at predetermined positions and thereafter electronic components 21a to 21e are mounted in a region BL1 and electronic components 22a and 22b in a region BL2.

A tip of the wiring pattern 12a-4 on the upper surface 11a of the extended polyimide sheet 11 constituting the flexible connector part 17 has conductive pads of generally a rectangular shape, as shown in the enlarged perspective view of FIG. 3D. The wiring pattern 12b-4 on the lower surface 11b of the polyimide sheet 11 is used as ground.

Next, as shown in FIG. 3B, a flexible wiring part 15 having wiring patterns 12a-3 and 12b-3 formed in the border area between a first circuit block (region BL1) and a second circuit block (region BL2) is bent in a U-character shape by directing the side mounting the electronic components 21a to 21e and 22a and 22b inward and the conductor of the wiring pattern 12b-3 outward, to thereby stack the first circuit block upon the second circuit block. Further, the extended flexible connector part 17 is bent near at the second circuit block (region BL2) to cover almost an opening of the first and second circuit blocks.

Next, as shown in FIG. 3C, a sealing resin 23 is filled in the space formed by a gap between the first and second circuit blocks and by the folded flexible connector part 17 to impart electromagnetic shielding effects. The sealing resin 23 is made of epoxy resin excellent in electric insulation dispersed with ferrite powders and ceramic powders. This structure is accommodated so as to keep the shape shown in the figure, for example, in a jig at a predetermined thickness, heated and cured to form the electronic device of the embodiment.

It may be understood easily that the circuit device and the manufacture method for a circuit device of the embodiment shown in FIGS. 3A to 3D may obtain similar operations and effects to those of the embodiment shown in FIGS. 1A to 1E.

Furthermore, in the embodiment shown in FIGS. 3A to 3D, while the four-layer flex-rigid board is manufactured, the extended flexible connector part 17 may be made easily. If necessary, either the wiring pattern 12a-4 on the upper surface 11a or the wiring pattern 12b-4 on the lower surface 11b may be used as an electromagnetic shield layer. Since this electromagnetic shield layer may make the circuit device have a tubular structure as a whole, large shielding effects may be obtained.

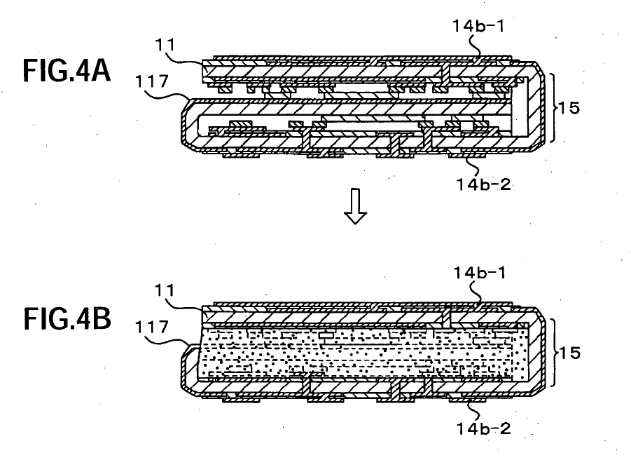

With reference to FIGS. 4A and 4B, description will be made on another preferred embodiment of a circuit device and a manufacture method for a circuit device of the present invention.

In the embodiment shown in FIGS. 3A to 3D, the polyimide sheet 11 with the wiring pattern extended from the end of the second circuit block is used as the flexible connector part. In the embodiment shown in FIGS. 4A and 4B, the flexible connector part is disposed between first and second circuit blocks.

In the following description of the embodiment shown in FIGS. 4A and 4B, similar elements to those of FIGS. 1A to 1E are represented by using identical reference symbols.

The circuit device of the embodiment is also manufactured by using a four-layer flex-rigid board as a base member. FIGS. 4A and 4B are manufacture process flow diagrams illustrating a manufacture method for the circuit device of the embodiment, following the process of manufacturing the flex-rigid board 10 shown in FIG. 3A.

FIG. 4A is a cross sectional view of the circuit device after a flexible wiring part is disposed between the first and second circuit blocks, and FIG. 4B is a cross sectional view of the circuit device formed by filling and curing insulating resin in the gap between the first and second circuit blocks.

The circuit blocks of the embodiment shown in FIGS. 4A and 4B are formed by mounting electronic components on the four-layer flex-rigid board with an extended polyimide sheet formed in a manner similar to that described with reference to FIG. 3A. In the embodiment shown in FIGS. 3A to 3D, the extended part is used as the flexible connector part 17, whereas in the embodiment shown in FIGS. 4A and 4B, the extended part is used as a flexible wiring part 117 used as an electromagnetic shield layer.

As shown in FIG. 4A, the flexible wiring part 117 is folded on an electronic component mounting surface side of the second circuit block and then the first circuit block is disposed covering the flexible wiring part.

As shown in FIG. 4B, a sealing resin 23 is filled in the gap between the first circuit blocks, flexible wiring part 117, and second circuit blocks to impart electromagnetic shielding effects. The sealing resin 23 is made of epoxy resin excellent in electric insulation dispersed with ferrite powders and ceramic powders. This structure is accommodated so as to keep the shape shown in the figure, for example, in a jig at a predetermined thickness, heated and cured to form the electronic device of the embodiment.

It may be understood easily that the circuit device and the manufacture method for a circuit device of the embodiment shown in FIGS. 4A and 4B may obtain similar operations and effects to those of the embodiment shown in FIGS. 1A to 1E.

Furthermore, in the embodiment shown in FIGS. 4A and 4B, the electronic components disposed in the first and second circuit blocks are perfectly separated by the electromagnetic shield layer so that mutual interferences between respective circuits may be suppressed almost perfectly, contributing greatly to stable operations of the circuit device.

In the above-described embodiments shown in FIGS. 1A to 4B, although two circuit blocks and one flexible wiring part 15 electrically connecting the two circuit blocks are used, the invention is not limited thereto, but three or more circuit blocks electrically connected by two or more flexible wiring parts 15 may also be used. These circuit blocks are folded and the sealing resin 23 is filled in gaps between blocks, and heated and cured to form circuit devices. It may be easily understood that these circuit devices may also obtain similar operations and effects to those of the above-described embodiments.

It may also be understood easily that leakage of electromagnetic waves from the circuit blocks to an external may be suppressed more, by extending the flexible wiring part to the outer side of the circuit device to cover it, similar to the embodiment shown in FIGS. 4A and 4B.

In the above-described embodiments shown in FIG. 1A to 4B, although a single circuit device is manufactured, a plurality of circuit devices may be manufactured at the same time by using a multi-device board.

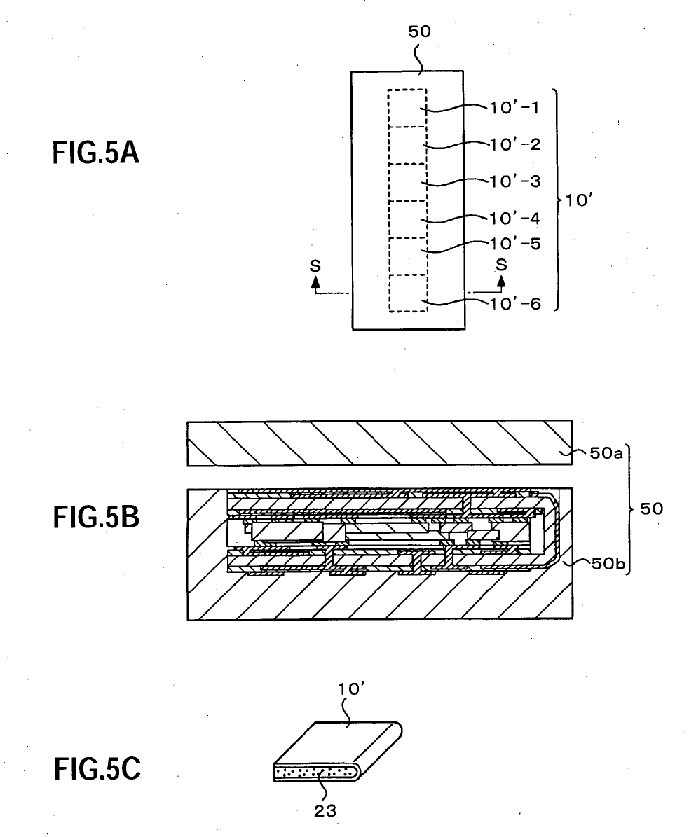

When a plurality of circuit devices of the embodiment shown in FIGS. 1A to 1E are manufactured at the same time, a multi-device board is first prepared which has a structure that a plurality of flex-rigid substrates shown in FIG. 1A are juxtaposed. Namely, the multi-device board is formed by juxtaposing first circuit blocks, second circuit blocks, and flexible wiring parts, one unit being a wiring board part constituted of a first circuit block, a second circuit block and a flexible wiring part 15. Next, electronic components are mounted and a sealing resin 23 is coated covering the electronic components and then folded. For example, this structure is accommodated, for example, in a lower mold 50b of a heating jig 50 shown in FIG. 5A (in this example, six circuit devices 10′-1 to 10′-6 may be manufactured at the same time) and FIG. 5B, and heated and cured while the structure is pressed by an upper mold 50a at a predetermined thickness shown in an enlarged cross sectional view of FIG. 5B, to thereby form a plurality of integrated circuit devices of a rod shape. This molded body constituted of a plurality of circuit devices is cut into discrete circuit devices such as shown in FIG. 5C.

Another flexible wiring part may be formed at one end of the first or second circuit block of the circuit device of the embodiment shown in FIGS. 1A to 1E. In the state that the circuit blocks are folded, the other flexible wiring part is connected to the other end of the first or second circuit block by solder to form a tubular body. Then, sealing resin is filled inside the tubular body and heated and molded in the shape of the tubular body. In this manner, a mechanical strength and electromagnetic shielding effects may be retained.

Boards other than the four-layer flex-rigid board may also be used. For example, a flex-rigid substrate may have both-sides polyimide wiring boards as third and fourth layers, a cover lay made of polyimide formed thereon, and first, second, fifth and sixth layers formed thereon via a glass epoxy resin layer, a flex-rigid substrate may have both-side polyimide wiring boards as third and fourth layers, a cover lay made of polyimide formed thereon, and first, second, fifth and sixth layers made of polyimide formed thereon.

A flex-rigid board may have both-side polyimide wiring boards as first and second layers and rigid boards bonded to polyimide boards as third, fourth, fifth and sixth layers.

In the above-described sealing resin 23 having the electric insulation and electromagnetic shielding effects, main epoxy resin may use epoxy resins having a product name WE-20/HV-19 (manufactured by Nippon Pelnox Corporation), having a product name EX-690/H-369 (manufactured by Sanyu Rec Co., Ltd.), having a product name Epikote 828/Epikure 113 (manufactured by Japan Epoxy Resins Co., Ltd.) and the like, and dispersant may use dispersant having a product name SN-dispersant 9228 (manufactured by San Nopco Limited), having a product name of Slosperse (manufactured by Avecia Ltd.) and the like.

Ferrite may be nickel zinc ferrite having a specific gravity of 4.9, and ceramic may be alumina powders or aluminum nitride powders. Alumina powders may have a grain diameter of f5 to 30 mm and aluminum nitride powders may have a grain diameter of f5 to 30 mm.

Used as the sealing resin 23 is 1) epoxy resin 30 wt %+ferrite 50 wt %+alumina 20 wt %+dispersant 1 wt % or smaller, 2) epoxy resin 30 wt %+ferrite 50 wt %+aluminum nitride 20 wt %+dispersant 1 wt % or smaller, or 3) epoxy resin 50 wt %+ferrite 20 wt %+alumina 30 wt %+dispersant 1 wt % or smaller. Since aluminum nitride has a high thermal conductivity, it is used in the case where a semiconductor device having a large consumption power or the like is mounted.

The circuit device and the manufacture method for a circuit device of the present invention are not limited to those described above, but obviously various structures may be used without departing from the gist of the present invention.

The present document contains subject matter related to Japanese Patent Application JP 2004-253592 filed in the Japanese Patent Office on Aug. 31, 2004, the entire contents of which being incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A circuit device including a plurality of circuit blocks, wherein:
on one surface of an insulating sheet having flexibility, a first wiring pattern and a second wiring pattern are formed, the second wiring pattern including a plurality of divisionally disposed patterns and electrically connected to the first wiring pattern each other;
in an area corresponding to the second wiring pattern on another surface of the insulating sheet, a third wiring pattern including a plurality of patterns is formed and electrically connected to the second wiring pattern via a conductive hole;
electronic components are mounted on the third wiring pattern so as to form the plurality of divisionally disposed circuit blocks;
the plurality of circuit blocks are folded by directing the electronic component mounting surface of the insulating sheet inward and the second wiring pattern outward; and
insulating resin having electromagnetic shielding effect is filled in gaps between the plurality of folded circuit blocks.

2. The circuit device according to claim 1, comprising two circuit blocks, wherein:
the first wiring pattern is used as a first flexible wiring part;
the second wiring pattern is used as an external layer wiring pattern;
the third wiring pattern is used as an internal layer wiring pattern; and
the two circuit blocks are folded in a U-character shape by directing the electronic component mounting surface of the two circuit blocks inward and the first flexible wiring part outward.

3. The circuit device according to claim 2, comprising conductive spacers connecting the inner layer wiring patterns of the facing circuit blocks and setting a predetermined gap when the circuit blocks are folded.

4. The circuit device according to claim 2, wherein the outer layer wiring patterns of the two circuit blocks and the first flexible wiring part constitute an electromagnetic shield layer.

5. The circuit device according to claim 2, wherein:
one of the external layer wiring patterns of the two circuit blocks is formed so as to have grid lands for connecting other wiring board.

6. The circuit device according to claim 2, wherein ends of the two circuit blocks on the side opposite to the first flexible wiring part are bonded together by low melting point metal in a state that the two circuit blocks are folded.

7. The circuit device according to claim 2, wherein:
a second flexible wiring part is formed on an end of the circuit block; and
contact terminals to another circuit are formed on the wiring pattern of the second flexible wiring part.

8. The circuit device according to claim 2, wherein:
a third flexible wiring part extending from a ground layer at the end of the circuit block may be formed;
the third flexible wiring part is folded on the mounting surface side of the electronic components; and
an electromagnetic shield layer is constituted of the outer layer wiring patterns and the third flexible wiring part.

9. A manufacture method of a circuit device including a plurality of circuit blocks, the method comprising the steps of:
forming a first wiring pattern on an insulating sheet;
forming an insulating layer and copper foil for forming second and third wiring patterns for forming respective divisionally disposed circuit block;
forming conductive holes for connection of necessary regions of the first, second and third wiring patterns;
forming the second and third wiring patterns;
forming solder resist on the third wiring patterns; and
mounting electronic components on the third wiring patterns,
thereby forming a plurality of circuit blocks relative to the divisionally disposed second and third wiring patterns,
the manufacture method further comprising the steps of:
folding the circuit patterns by directing an electronic component mounting surface side of the insulating sheet inward and the first wiring patterns outward;
filling insulating resin having electromagnetic shielding effect between the electronic component mounting surfaces the plurality of folded circuit blocks; and
heating and curing the insulating resin.

10. The manufacture method for a circuit device according to claim 9, wherein,
the insulating sheet includes polyimide; and
the insulating resin having electromagnetic shielding effect, includes epoxy resin dispersed with ferrite powders and ceramic powders.
